(19) United States
(12) Patent Application Publication
(10) Pub. No.: US 2009/0115069 A1
(43) Pub. Date: May 7, 2009

(54) SEMICONDUCTOR CHIP PACKAGE AND METHOD OF MANUFACTURING THE SAME

(75) Inventors: Young-Lyong KIM, Gyeonggi-do (KR); Jong-Ho LEE, Chungcheongnam-do (KR); Min-Ho O, Daegu (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/172,912

(22) Filed: Jul. 14, 2008

(30) Foreign Application Priority Data
Nov. 1, 2007 (KR) 2007-0110814

(51) Int. Cl. H01L 23/00; H01L 21/50; H05K 7/00

(52) U.S. Cl. 257/777; 438/109; 361/820; 257/E23.001; 257/E21.499

(57) ABSTRACT

A semiconductor chip package having a molding layer is provided. The semiconductor chip package includes a semiconductor chip, a plurality of external connection terminals, and the molding layer. The semiconductor chip comprises a backside surface, side surfaces, and an active surface having a plurality of chip pads disposed thereon. The molding layer substantially covers the backside surface, the side surfaces, and the active surface of the semiconductor chip and defines at least one opening exposing a portion of the backside surface of the semiconductor chip. A multi-chip package including the semiconductor chip package and a method of manufacturing the semiconductor chip package are also provided.

### CROSS-REFERENCE TO RELATED APPLICATIONS

This U.S. non-provisional patent application claims priority under 35 U.S.C. §119 to Korean Patent Application No. 2007-0110814 filed on Nov. 1, 2007, the entire contents of which are hereby incorporated by reference.

### BACKGROUND

The present invention relates to a semiconductor chip package and a method of forming the same. More particularly the present invention relates to a semiconductor chip package having a molding layer disposed on a backside surface, side surfaces and an active surface of a semiconductor chip and a method of forming the same.

### SUMMARY

Some embodiments of the present invention provide a semiconductor chip package having a molding layer. The semiconductor chip package includes a semiconductor chip, a plurality of external connection terminals, and the molding layer. The semiconductor chip comprises a backside surface, side surfaces, and an active surface having a plurality of chip pads disposed thereon. The molding layer substantially covers the backside surface, the side surfaces, and the active surface of the semiconductor chip and defines at least one opening exposing a portion of the backside surface of the semiconductor chip.

The semiconductor chip package according to some embodiments of the present invention has improved resistance to cracking and chipping. Further, because the semiconductor chip package includes the molding layer on all six sides of the semiconductor chip, underfill and back-side protection processes are not needed. Therefore, the process for manufacturing the semiconductor chip package can be simpler and less costly than conventional methods.

### BRIEF DESCRIPTION OF THE DRAWINGS

The above and other features and advantages of the present invention will become more apparent by describing in detail example embodiments thereof with reference to the accompanying drawings, in which:

FIG. 1 is a plan view of a semiconductor chip package according to some embodiments of the present invention;

FIG. 2 is a cross-sectional view of the semiconductor chip package of FIG. 1 along line A-A′;

FIG. 3 is a cross-sectional view of a multi-chip package including the semiconductor chip package of FIG. 1, according to some embodiments of the present invention;

FIGS. 4 through 7 are cross-sectional views illustrating a method of manufacturing a semiconductor chip package according to some embodiments of the invention;

FIG. 8 is a plan view of a wafer illustrating an alternate embodiment for manufacturing a semiconductor chip package;

FIG. 9 is a perspective view of a semiconductor chip package according to some embodiments of the present invention;

FIG. 10 is a plan view of the semiconductor chip package of FIG. 9;

FIG. 11 is a cross-sectional view of the semiconductor chip package of FIGS. 9 and 10, taken along line B-B′;

FIG. 12 is a cross-sectional view of a multi-chip package including the semiconductor chip package of FIG. 9, according to some embodiments of the present invention;

FIG. 13 is a plan view illustrating a main mold for use in a method of manufacturing a semiconductor chip package according to some embodiments of the present invention;

FIGS. 14 through 16 are cross-sectional views taken along line C-C′ of FIG. 13 illustrating a method of manufacturing a semiconductor chip package according to some embodiments of the present invention;

FIG. 17 is a plan view of a memory card system including a semiconductor chip package according to some embodiments of the present invention; and

FIG. 18 is a plan view of an electronic apparatus including a semiconductor chip package according to some embodiments of the present invention.

### DETAILED DESCRIPTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations accordingly, for example, of manufacturing techniques and/or tolerances, are to be expected. Thus, example embodiments of the present invention should not be construed as limited to the particular shapes of components illustrated herein but are to include deviations in shapes that result, for example, from manufacturing. Thus, the components illustrated in the figures are schematic in nature and their shapes are not intended to illustrate the actual shape of a component of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

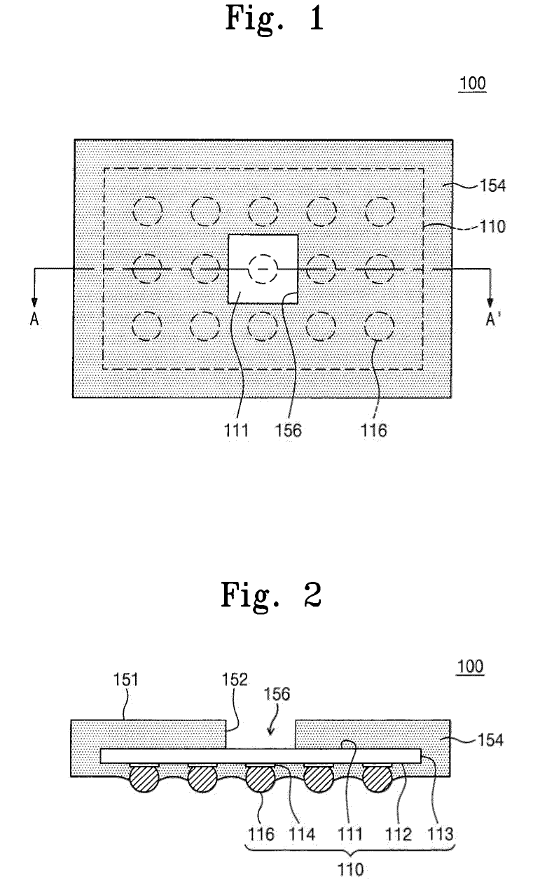

FIG. 1 is a plan view of a semiconductor chip package according to some embodiments of the present invention. FIG. 2 is a cross-sectional view of the semiconductor chip package of FIG. 1 along line A-A′.

Referring to FIGS. 1 and 2, a semiconductor chip package 100 includes a semiconductor chip 110, a molding layer 154, and a plurality of external connection terminals 116 such as solder balls. The semiconductor chip 110 includes a backside surface 111, side surfaces 113 (typically four side surfaces in the case of a conventional chip), and an active surface 112 upon which a plurality of chip pads 114 are formed. The external connection terminals 116 are disposed on the chip pads 114 of the semiconductor chip 110. The molding layer 154 of the semiconductor chip package 100 defines an opening 156 defined over the backside surface 111 of the semiconductor chip 110.

As shown in FIGS. 1 and 2, the molding layer 154 covers all six surfaces of the semiconductor chip 110 with the exception of the opening 156. Therefore, the molding layer provides protection to the semiconductor chip 110 on all sides. The semiconductor chip 110 also has a plurality of edges defined by the active, backside, and side surfaces. Because the edges of the semiconductor chip 110 are covered by the molding layer 154, the edges are protected from chipping, unlike in the conventional process.

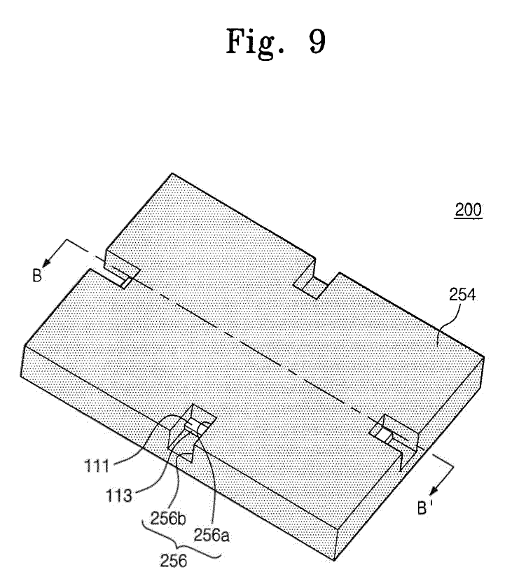

As described below, the opening 156 may be located at a substantially center portion of the semiconductor chip 110. Alternatively, the opening 156 may be located at one or more center edge portions of the semiconductor chip 110 as discussed with respect to FIG. 9 further below. The opening 156 formed in the molding layer 154 defines a step. In particular, the step may be defined by a top surface 151 and an inner wall 152 of the molding layer 154.

A portion of the molding layer 154 that covers the active surface 112 exposes a portion of the external connection terminals 116 and forms a concave surface between the external connection terminals 116 and below a top of the external connection terminals 116 such that the external connection terminals can be firmly fixed to the semiconductor chip 110. In other words, the molding layer 154 can provide structural support to the joints between the external connection terminals 116 and the chip pads 114, thereby improving the reliability of the joints. Also, because all of the main surfaces, including side surfaces, of the semiconductor chip 110 are covered with the molding layer 154, a costly BSP layer is not required according to some embodiments of the present invention.

According to one embodiment, the opening 156 may be filled with a thermally conductive material (not illustrated), such as copper or silver, can be disposed within the opening 156 to improve the heat dissipation from the semiconductor package 100 when it is in actual use.

Additionally, an adhesive layer, i.e., an epoxy type adhesive, can be disposed between the thermally conductive material and the exposed chip 110 for electrical isolation therebetween.

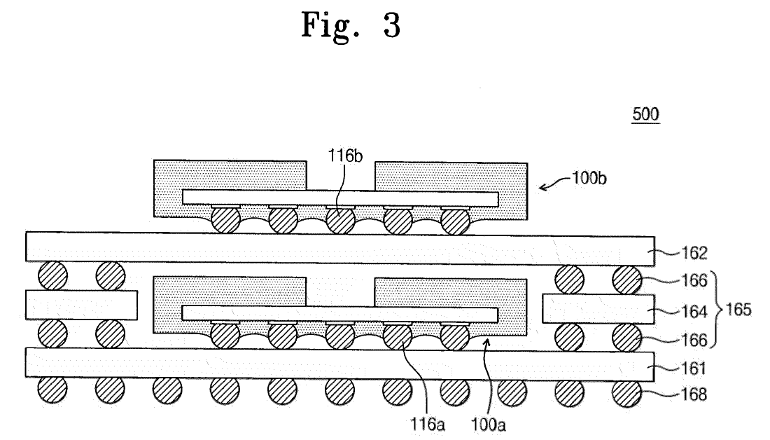

FIG. 3 is a cross-sectional view of a multi-chip package including the semiconductor chip package of FIG. 1, according to some embodiments of the present invention.

Referring to FIG. 3, the multi-chip package 500 includes a lower semiconductor chip package 100a, an upper semiconductor chip package 100b, a lower substrate 161, an upper substrate 162, and a plurality of external connection terminals 168 such as solder balls. The lower semiconductor package 100a and the upper semiconductor package 100b may have structures same as or similar to those discussed with respect to FIGS. 1 and 2. The lower semiconductor chip package 100a is disposed on the lower substrate 161 and electrically connected to the lower substrate 161 by the lower chip external connection terminals 116a. The upper semiconductor chip package 100b is disposed on the upper substrate 162 and electrically connected to the upper substrate 162 by the upper chip external connection terminals 116b. The upper substrate 162 is stacked on the lower substrate 161 using a connection means 165. The connection means 165 may include one or more sub-PCBs 164 and a plurality of intermediate external connection terminals 166 that electrically connect the upper and lower substrates 161 and 162.

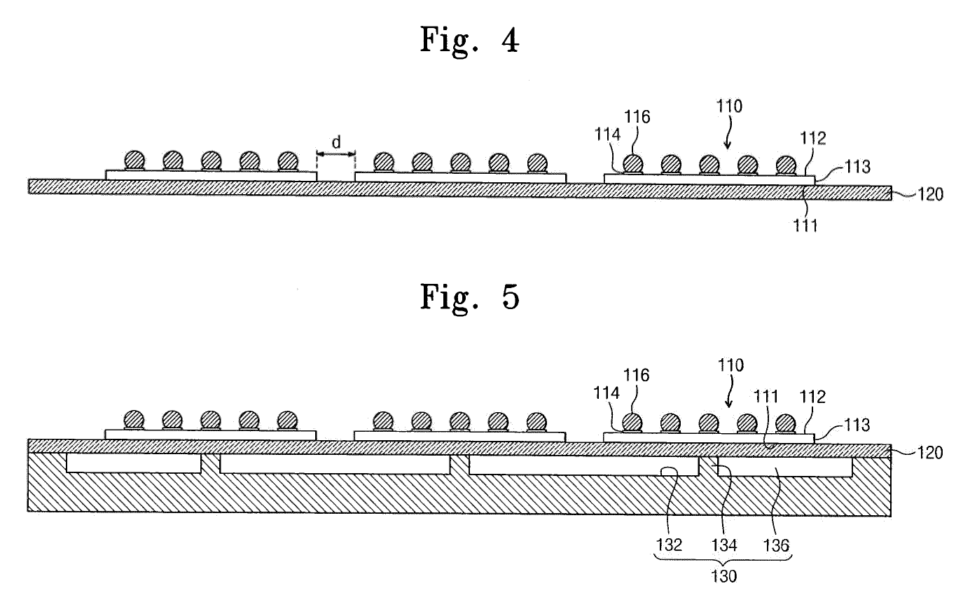

FIGS. 4 through 7 are cross-sectional views illustrating a method of manufacturing a semiconductor chip package such as one shown in FIG. 1 according to some embodiments of the invention. When the fabrication method is described below, processes which can be performed according to processing operations well known to those of ordinary skill in the art will be omitted or very briefly described for the sake of brevity.

Referring to FIG. 4, a plurality of semiconductor chips 110 are attached to a carrier tape 120. Each of the semiconductor chips 110 includes a backside surface 111, side surfaces 113, and an active surface 112 having a plurality of chip pads 112 disposed thereon. The backside surface 111 of the semiconductor chips 110 is attached to the carrier tape 120 by, for example, an adhesive in the carrier tape 120. The semiconductor chips 110 are spaced apart on the carrier tape 120 by a pre-determined distance d. The carrier tape 120 may be a polyimide tape. The thickness of the carrier tape 120 can be in the range of about 20 μm to about 30 μm, and more preferably about 25 μm.

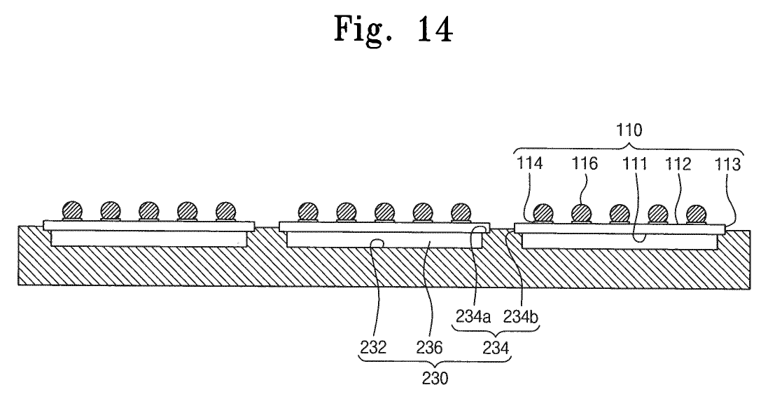

Referring to FIG. 5, the carrier tape 120, including the semiconductor chips 110, is loaded onto a main mold 130. The main mold 130 includes a void or molding space 136. The main mold 130 also includes a bottom surface 132, and projections 134 that contact the carrier tape 120. The distance between the projecting portions 134 may be determined by factors such as the size of the semiconductor chips 110 and/or the distance d. Each projecting portion 134 can be disposed so as to correspond to one of the semiconductor chips 110. For example, each projecting portion 134 can correspond approximately to the center of each corresponding semiconductor chip 110. However, the projecting portions 134 can also be disposed at end portions of each corresponding semiconductor chip 110. In this case, the projecting portions 134 can help support the semiconductor chips 110 that are adjacent to the corresponding semiconductor chip 110 as discussed with respect to FIG. 14 further below.

The back surfaces 111 of the semiconductor chips 110 face toward the main mold 130 for a compression molding process to be performed at a subsequent step.

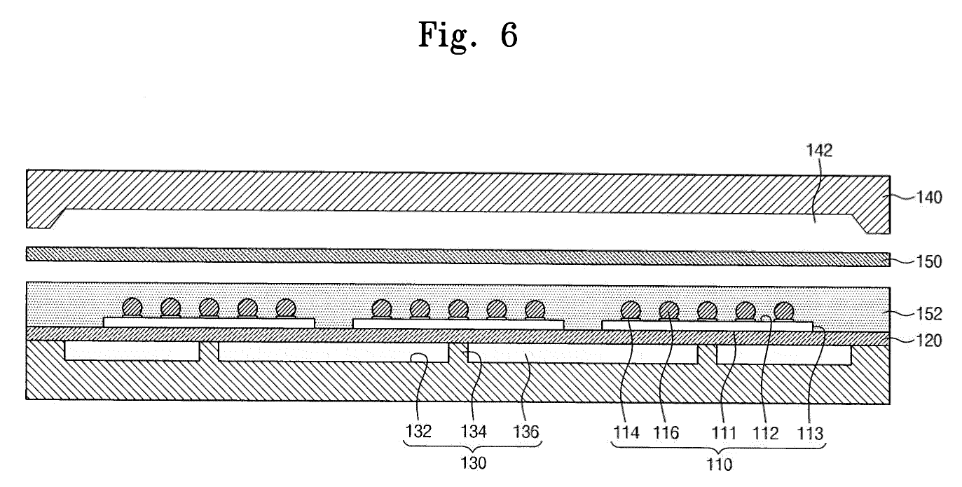

Referring to FIG. 6, a subsidiary mold 140 having a molding part or molding recess 142 is provided over the carrier tape 120 so as to face the active surface 112 of the semiconductor chip 110.

A release tape 150 is also provided over the carrier tape 120 between the subsidiary mold 140 and the main mold 130. The release tape 150 may be supplied from a tape roller (not illustrated) located on both sides of the molds 130, 140. The thickness of the release tape 150 is in the range of about 50 to about 400 μm. The release tape 150 may be PolyTetraFluoroEthylene (PTFE) or Ethylene TetraFluoroEthylene copolymer (ETFE). The release tape 150 may be formed of a material that does not easily transform during the compression molding process.

In addition, a molding material 152 is dispensed on the semiconductor chips 110 and the carrier tape 120 at room temperature. The molding material 152 is located between the release tape 150 and the semiconductor chip 110 having external connection terminals 116. In one embodiment, the molding material 152 may be dispensed between the release tape 150 and the semiconductor chip 110 after the release tape 150 is conformally attached to the molding part 142 of the subsidiary mold 140. The molding material 152 may be an epoxy molding compound (EMC). The EMC may be in the form of a powder or liquid. The EMC may include about 50 to about 90 wt % silica and have a coefficient of thermal expansion of about 50 ppm/° C. below the glass transition temperature. The molding may also be formed of a silicone material.

Then, the molds 130, 140 may be heated to a temperature range of about 100° C. to about 200° C., for example about 175° C., for more than 2 seconds such that the viscosity of the molding material 152 is properly reduced. For example, although not fixed, the viscosity of the molding material 152 may be about 20 to 70 poise or higher and the molding material 152 may have a spiral flow rate of about 40 to about 140 inches during the molding process.

The heating process is performed to transform the powder into a liquid form if the power is employed in the molding process.

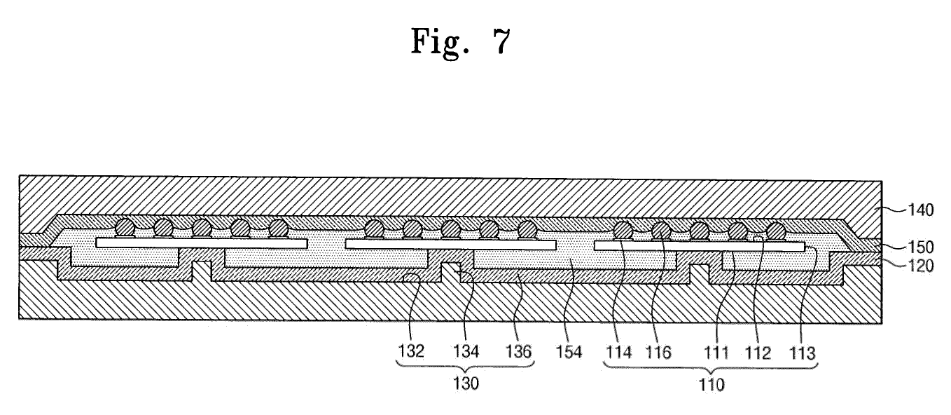

Also, during this heating process, the molding part 142 is exhausted (evacuated) by vacuum at a pressure of about 50 Torr within the molding part 142 such that a molding layer 154 shown in FIG. 7 can be uniformly formed from the molding material 152.

According to one aspect of the present invention, the molds 130, 140 may be formed of a material having a coefficient of thermal expansion different from that of the molding material 152 such that the molded semiconductor package shown in, for example, FIG. 2, can be easily released from the molds 130, 140 after the molding process. Also, the difference in the coefficient of thermal expansion between the carrier tape 120 and the molding material 152 may be greater than 10 ppm such that the carrier tape 120 can be easily separated from the molding layer 154.

Referring to FIG. 7, a compression molding process is performed to force the molding material 152 to fill the molding space 136 such that the molding material 152 covers a portion of the backside surface 111, the active surface 112, and the side surfaces 113 of the semiconductor chips 110.

During the compression molding process, the main mold 130 and the subsidiary mold 140 are compressed against each other. As a result, the release tape 150 and the semiconductor chip 110 between the molds 130, 140 are also compressed against each other with the molding material 152 between them.

As shown in FIG. 7, a portion of the backside surface 111 of the semiconductor chips 110, e.g., the portion overlying the projecting portion 134, and the external connection terminals 116 are not covered by the molding material.

During the compression molding process, the carrier tape 120 is conformally adhered to the bottom surface 132 of the main mold 130 due to the pressure exerted by the molding material 152 filling the molding space 136. Also, the release tape 150 may be adhered to the subsidiary mold 140 due to the compression molding process.

Further, the external connection terminals 116 can protrude above a top surface of the molding layer 154. In other words, an upper portion of the external connection terminals are exposed from the molding layer 154.

In one embodiment, the molding layer 154 forms a concave top surface between the external connection terminals 116 and below a top of the external connection terminals 116. The height of the concave top surface can be substantially the same or less than a height of the external connection terminals 116, but higher than half the height of the external connection terminals 116. As a result, without additional processing steps, e.g., a coating process to provide a support at the joints of the external connection terminals 116 and the chip pads 114, the external connection terminals 116 can be firmly secured to the semiconductor chips 110.

As a result, an underfill process may not be required unlike the prior art. Consequently, the board-level reliability can be improved without the costly underfill process and the overall assembly time can be significantly reduced, thereby reducing the overall manufacturing costs.

After forming the molding layer 154, an additional curing step at greater than 100° C. may be performed to improve the adhesion between the semiconductor chips 110 and the molding layer 154 and to increase the integrity of the molding layer 154.

The main mold 130 and the subsidiary mold 140 are then separated from the semiconductor chips 110. Because the carrier tape 120 and the release tape 150 are adhered to the main mold 130 and subsidiary mold 140, respectively, the carrier tape 120 and the release tape 150 are also removed from the semiconductor chips 110 when the main mold 130 and the subsidiary mold 140 are separated. The area of the backside surface 111 overlying the projecting portion 134 will later define an opening 156 when the molds 130, 140 are separated.

The manufacturing of the semiconductor package 100 shown in FIG. 1 is then completed by sawing the semiconductor chips 110 into individual semiconductor chip packages 100. For example, the molding layer 154 is cut by a blade or a laser between the semiconductor chips 110 to be singulated.

The semiconductor chip packages 100 manufactured according to the method of this embodiment include a molding layer 154 on all six sides of the semiconductor chips 110. Thus, the semiconductor chip packages 100 are less susceptible to damage from the external environment and failure during testing.

Thus, the chipping or cracking problems in the prior art can be substantially reduced. Also, no BSP layer is required. Further, because the above processes are performed on selected semiconductor chips, the above processes need only be performed on semiconductor chips that are found to pass a testing step. Therefore, the manufacturing cost is reduced as compared to the conventional BSP process where both good and bad semiconductor chips are processed. Because EMC is typically less expensive than BSP materials, the cost of the process according to embodiments of the present invention can be reduced as compared to the conventional process.

A person of ordinary skill in the art will appreciate that the thickness of the molding layer 154 on the backside surface 111 of the semiconductor chips 110 can be adjusted by controlling the depth of the molding space 136 and/or the thickness of the carrier tape 120. Therefore, according to some embodiments of the present invention, the thickness of the semiconductor package 110 can be easily adjusted, which is not available in the conventional process because the BSP tape typically has a pre-determined thickness.

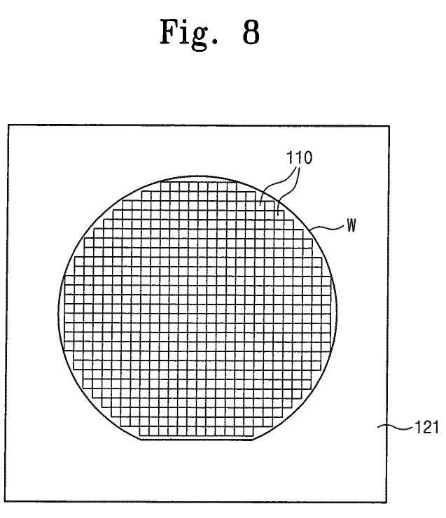

FIG. 8 is a plan view of a wafer illustrating an alternate embodiment for manufacturing a semiconductor chip package.

Referring to FIG. 8, a semiconductor chip package 100 can be manufactured at a wafer level. Specifically, a wafer including a plurality of semiconductor chips 110 is mounted on an elastic carrier tape 121. The wafer W is then diced according to conventional processes, for instance, using a high-speed diamond blade. Next, the elastic carrier tape 121 is expanded so that a minimum distance d (as shown in FIG. 4) is achieved between adjacent semiconductor chips 110. The individual semiconductor chip packages 100 can then be manufactured as described above with respect to FIGS. 4 through 7.

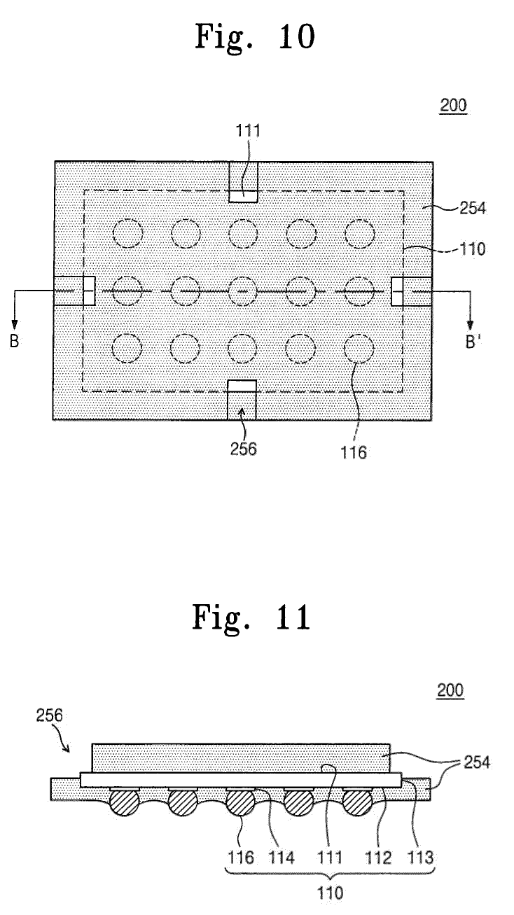

FIG. 9 is a perspective view of a semiconductor chip package according to another embodiment of the present invention. FIG. 10 is a plan view of the semiconductor chip package of FIG. 9. FIG. 11 is a cross-sectional view of the semiconductor chip package of FIGS. 9 and 10, taken along line B-B′.

Referring to FIGS. 9 through 11, a semiconductor chip package 200 includes a semiconductor chip 110, a plurality of external connection terminals 116 such as solder balls, and a molding layer 254. The semiconductor chip 110 includes a backside surface 111, side surfaces 113, and an active surface 112 upon which a plurality of chip pads 114 are disposed. The semiconductor chip 110 has a plurality of edges defined by the backside surface 111 (or active surface 112) and side surfaces 113. The external connection terminals 116 are disposed on the chip pads 114. The opening 256 includes a first opening 256a and a second opening 256b. The first opening 256a and the second opening 256b collectively define the opening 256. The first opening 256a exposes a portion of the backside surface 111 of the semiconductor chip 110 that is adjacent to an edge of the semiconductor chip 110. The second opening 256b exposes a portion of the side surface 113 of the semiconductor chip 110 that is adjacent to the edge of the semiconductor chip 110. The opening 256 may be formed at a substantially center portion of the corresponding edge of the semiconductor chip 110.

In one aspect, the exposed portion of the side surface 113 of the semiconductor chip 110 and the exposed portion of the backside surface 111 forms a step within the at least one opening 256.

In one aspect, substantial portions of the edges of the semiconductor chip 110 are covered by the molding layer 254 such that the edges are protected from chipping or external impacts, unlike in the prior art. The molding layer 254 exposes a portion of the external connection terminals 116 and also has a concave top surface between the external connection terminals 116 and below a top of the external connection terminals 116 such that the external connection terminals 116 can be firmly fixed to the semiconductor chip 110.

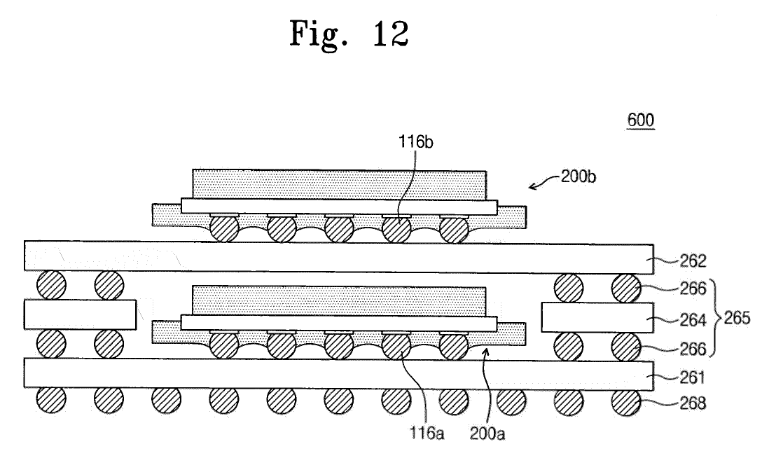

FIG. 12 is a cross-sectional view of a multi-chip package including the semiconductor chip package of FIG. 9, according to some embodiments of the present invention. The lower semiconductor package 200a and the upper semiconductor package 200b may have structures same as or similar to those discussed with respect to FIGS. 1 and 2.

Referring to FIG. 12, the multi-chip package 600 includes a lower semiconductor chip package 200a, an upper semiconductor chip package 200b, a lower substrate 261, an upper substrate 262, and a plurality of external connection terminals 268. The lower semiconductor chip package 200a is disposed on the lower substrate 261 and is electrically connected to the lower substrate 261 by the lower chip external connection terminals 116a. The upper semiconductor chip package 200b is disposed on the upper substrate 262 and is electrically connected to the upper substrate 262 by the upper chip external connection terminals 116b. The upper substrate 262 is stacked on the lower substrate 261 using a connection means 265. The connection means 265 may include one or more sub-PCBs 264 and a plurality of intermediate external connection terminals 266 that electrically connect the upper and lower substrates 261 and 262 to each other.

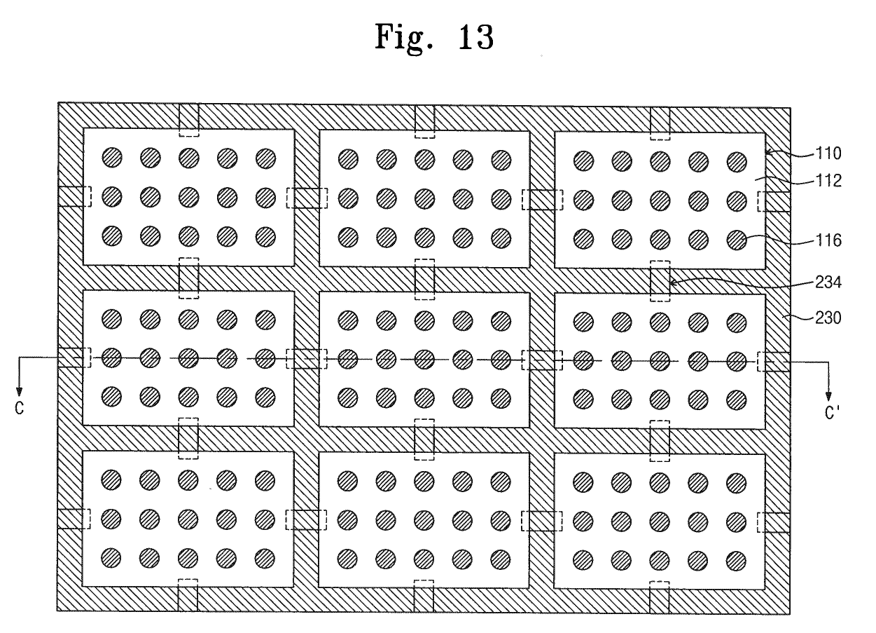

FIG. 13 is a plan view illustrating a main mold for use in a method of manufacturing a semiconductor chip package such as one shown in FIG. 9 according to some embodiments of the present invention. FIGS. 14 through 16 are cross-sectional views taken along line C-C′ of FIG. 13 illustrating a method of manufacturing a semiconductor chip package according to some embodiments of the present invention. When the fabrication method is described below, processes which can be performed according to processing operations well known to those of ordinary skill in the art will be omitted or very briefly described for the sake of brevity.

In the following discussion of the embodiment of FIGS. 14 through 16, description of the common parts to the above-mentioned embodiment may be omitted, and only differences may be described.

Referring to FIG. 13 and FIG. 14, a main mold 230 includes bottom surfaces 232 and projecting portions 234 each extending from corresponding ones of bottom surfaces 232. The projecting portions 234 and the bottom surface 232 collectively define a molding space 236. The projecting portions 234 are arranged so as to correspond to edges of semiconductor chips 110. In other words, the edges of the semiconductor chips 110 are placed on the projecting portions 234 as explained further below. The projecting portion 234 includes a step portion 234a for forming the first opening 256a and a side portion 234b for forming the second opening 256b of the semiconductor chip package 200. The step portion 234a is disposed at a height lower than that of a top surface of the projecting portion 234.

Referring to FIG. 14, a plurality of semiconductor chips 110 are loaded onto a main mold 230 with the backside surface 111 of the semiconductor chips 110 contacting a portion of the projecting portion 234 of the main mold 230. A portion of the backside surface 111 of the semiconductor chips 110 may contact the step portion 234a of the projecting portion 234 and a portion of the side surface 113 of the semiconductor chips 110 may contact the side portion 234b of the main mold 230.

The projecting portion 234 of the main mold 230 may be arranged on at least two edge portions of the semiconductor chips 110 and preferably, the projecting portion 234 of the main mold 230 is arranged on four edge portions of the semiconductor chips 110. In one embodiment, each of the projecting portions 234 of the main mold 230 is configured to support a pair of adjacent semiconductor chips 110.

The main mold 230 includes voids or molding spaces 236 disposed under the semiconductor chips 110.

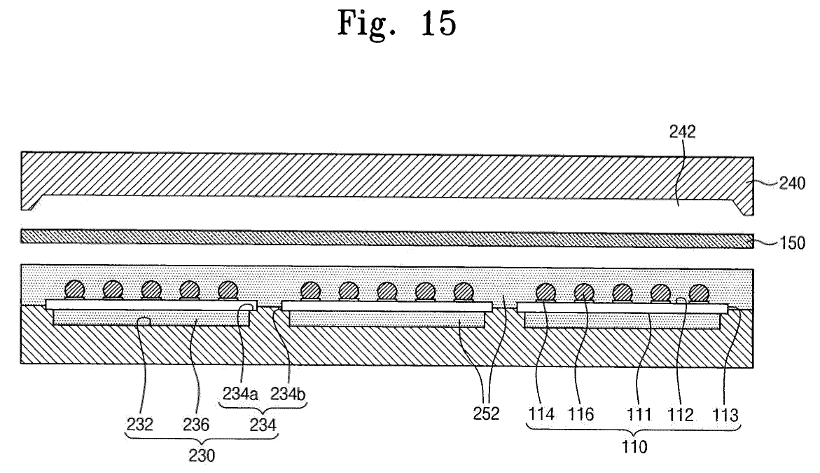

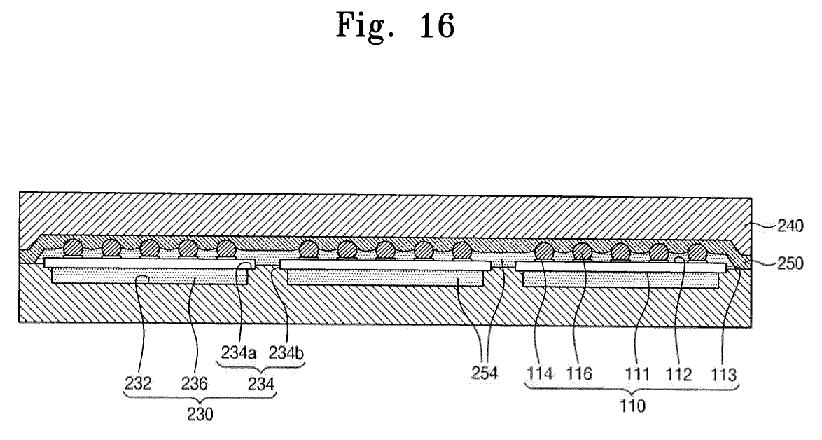

Referring to FIG. 15, using a process similar to the process described above with respect to FIG. 6, a molding material 252 is provided between a subsidiary mold 240 and the main mold 230. The molding material 252 is dispensed over the semiconductor chip 110. In the embodiment shown in FIG. 6, the molding material 152 is provided over the carrier tape 120 and does not fill the molding space 136 due to the presence of the carrier tape 120. In contrast, in the present embodiment, the molding material 252 fills the molding space 236 due to the absence of the carrier tape 120. Also, a release tape 150 is provided between the subsidiary mold 240 and the molding material 252.

The molding material 252 may be an epoxy molding compound (EMC). The EMC may be in the form of a powder or liquid. The EMC may include about 50 to about 90 wt % silica and have a coefficient of thermal expansion of about 50 ppm/° C. below the glass transition temperature.

A release tape 150 is also provided between the subsidiary mold 240 and the main mold 230. The release tape 150 may be supplied from a tape roller (not illustrated) located on both sides of the molds 230, 240. The thickness of the release tape 150 is in the range of about 50 to about 400 μm. The release tape 150 may be PolyTetraFluoroEthylene (PTFE) or Ethylene TetraFluoroEthylene copolymer (ETFE). The release tape 150 may be formed of a material that does not easily transform during the compression molding process.

In addition, a molding material 252 is dispensed on the semiconductor chips 110 having external connection terminals 116 at room temperature. The molding material 252 is located between the release tape 150 and the main mold 230. In one embodiment, the molding material 252 may be dispensed between the release tape 150 and the semiconductor chip 110 after the release tape 150 is conformally attached to the molding part 242 of the subsidiary mold 240.

The molding material 252 may be an epoxy molding compound (EMC). The EMC may be in the form of a powder or liquid. The EMC may include about 50 to about 90 wt % silica and have a coefficient of thermal expansion of about 50 ppm/° C. below the glass transition temperature.

Then, the molds 230, 240 may be heated to a temperature range of about 100° C. to about 200° C., for example about 175° C., for more than 2 seconds such that the viscosity of the molding material 252 is properly reduced for the compression molding process. For example, although not fixed, the viscosity of the molding material 152 may be about 20 to 70 poise or higher and the molding material 152 may have a spiral flow rate of about 40 to about 140 inches during the molding process.

The heating process is performed to transform the powder into a liquid form if the power is employed in the molding process.

Also, during this heating process, the molding part 242 is exhausted (evacuated) by vacuum at a pressure of about 50 Torr within the molding part 242 such that a molding layer 254 shown in FIG. 16 can be uniformly formed from the molding material 252.

According to one aspect of the present invention, the molds 230, 240 may be formed of a material having a coefficient of thermal expansion different from that of the molding material 252 such that the molded semiconductor package shown in, for example, FIG. 9, can be easily released from the molds 230, 240 after the molding process.

Referring to FIG. 16, a compression molding process is performed to force the molding material 252 to fill the molding spaces 236 such that the molding material 252 covers a portion of the backside surface 111, the active surface 112, and the side surfaces 113 of the semiconductor chips 110. As shown in FIG. 16, a portion of the backside surface 111 of the semiconductor chips 110, a portion of the side surfaces 113 of the semiconductor chips 110, and the external connection terminals 116 are not covered by the molding material 252. During the compression molding process, the release tape 250 is adhered to the subsidiary mold 240 due to the compression molding process.

The main mold 230 and the subsidiary mold 240 are then separated from the semiconductor chips 110. Because the release tape 250 is adhered to the subsidiary mold 240, the release tape 250 is removed from the semiconductor chips 110 when the main mold 230 and the subsidiary mold 240 are separated. The area of the backside surface 111 overlying the projecting portion 234 and the portion of the side surface 113 in contact with the projecting portion 234 will later define the opening 256 when the molds 230, 240 are separated.

Then, the semiconductor chips 110 are singulated into individual semiconductor chip packages 200 shown in FIG. 11. The semiconductor chip packages 200 manufactured according to the method of this embodiment include a molding layer 254 on all six sides of the semiconductor chips 110. Thus, the semiconductor chip packages 200 are less susceptible to damage from the external environment and failure during testing.

Thus, with embodiments of the invention discussed above, the chipping or cracking problems in the prior art can be substantially reduced. Also, no expensive BSP layer is required. Further, because the above processes are performed on selected semiconductor chips, the above processes need only be performed on semiconductor chips that are found to pass a testing step, e.g., a known-good die (KGD). Therefore, the manufacturing cost is reduced as compared to the conventional BSP process where both good and bad semiconductor chips are processed. Because EMC is typically less expensive than BSP materials, the cost of the process according to embodiments of the present invention can be reduced as compared to the conventional process.

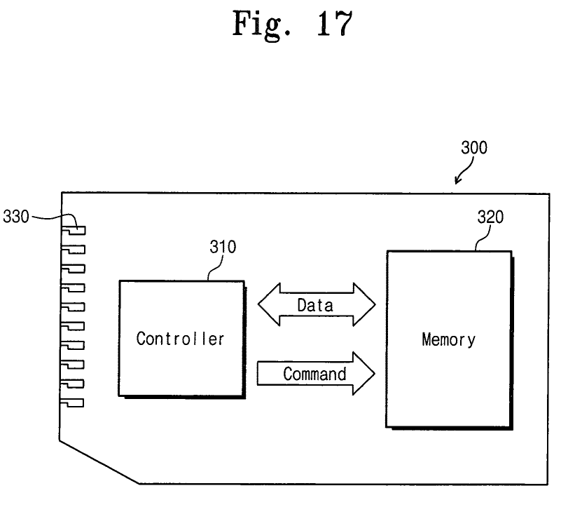

FIG. 17 is a plan view of a memory card system including a semiconductor chip package according to embodiments of the present invention.

Referring to FIG. 17, a memory card system 300 includes a controller 310 and a memory 320. The controller 310 may comprise a microprocessor, a digital signal processor, and/or a microcontroller. The memory 320 may include, but not limited to, a dynamic random access memory (DRAM), a flash memory, a phase-change random access memory (PRAM), a static random access memory (SRAM), and/or a magnetic random access memory (MRAM). The memory 310 may be included in a semiconductor chip package according to embodiments of the present invention and may be, for instance, a semiconductor chip package 100 or 200, as described above. Also, the memory 310 may be included in a multi-chip package (MCP) according to embodiments of the present invention and may be, for instance, a multi-chip package 500 or 600, as described above.

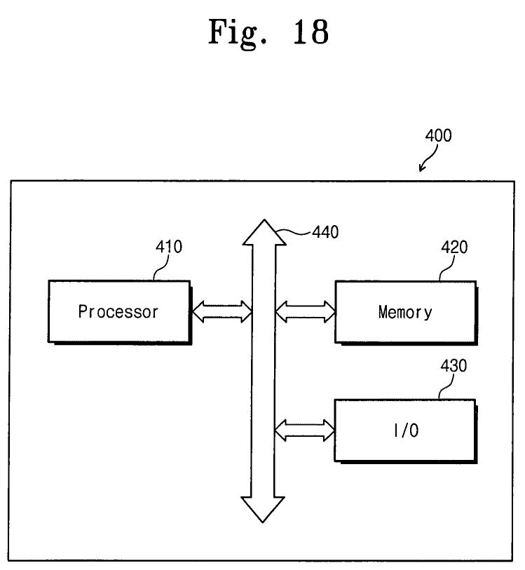

FIG. 18 is a plan view of an electronic apparatus including a semiconductor chip package according to some embodiments of the present invention.

Referring to FIG. 18, an electronic apparatus 400 includes a processor 410, an I/O chip 430, a memory 420, and a bus 440 electrically connecting the processor 410, the I/O chip 430, and the memory 420. The memory 420 is included in a semiconductor chip package according to some embodiments of the present invention and may be, for instance, a semiconductor chip package 100 or 200, as described above. Also, the memory 420 may be included in a multi-chip package according to embodiments of the present invention and may be, for instance, a multi-chip package 500 or 600, as described above.

According to some embodiments of the present invention, a semiconductor chip package includes a molding layer on all sides, e.g., six sides, of a semiconductor chip. Thus, the semiconductor chip package is less susceptible to cracking and chipping. Further, underfill and back-side protection (BSP) processes may not be needed. Therefore, the process for manufacturing the semiconductor chip package can be simplified and the expense of the process can be reduced. Also, because the molding layer surrounds joints between the chip pads and the external connection terminals, the joint reliability can be improved without the underfill process.

A person of ordinary skill in the art will appreciate that a semiconductor chip can have more or fewer than six sides and that the above-described processes can be applied to such semiconductor chips, within the spirit and scope of the present invention.

According to some embodiments of the present invention, a molding layer is formed on both the front and back sides of a semiconductor chip substantially simultaneously in a single process. Therefore, the processing time and expense is reduced as compared to conventional processes. Further, a minimum amount of the semiconductor chip is exposed outside of the molding layer, so that the occurrence of chipping of the semiconductor chip (at a subsequent testing step for example) can be reduced.

Lastly, embodiments and concepts of the present invention can be readily applied to semiconductor packages such as a wafer level package (WLP). However, concepts of the present invention can be also useful to other similar conventional semiconductor packages within the spirit and scope of the present invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Various operations will be described as multiple discrete steps performed in a manner that is most helpful in understanding the invention. However, the order in which the steps are described does not imply that the operations are order-dependent or that the order that steps are performed must be the order in which the steps are presented.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. The present invention is defined by the following claims, with equivalents of the claims to be included therein.

What is claimed is:

1. A semiconductor chip package, comprising:
a semiconductor chip including:
a backside surface;
side surfaces; and
an active surface having a plurality of chip pads;
a plurality of external connection terminals disposed on the chip pads of the semiconductor chip; and
a molding layer, wherein the molding layer substantially covers the backside surface, the side surfaces, and the active surface of the semiconductor chip and wherein the molding layer defines at least one opening exposing a portion of the backside surface of the semiconductor chip.

2. The semiconductor package of claim 1, further comprising a thermally conductive material disposed within the at least one opening, the thermally conductive material contacting the backside surface.

3. The semiconductor package of claim 1, wherein the at least one opening in the molding layer forms a step.

4. The semiconductor package of claim 3, wherein the step is defined by a top surface and an inner wall of the molding layer.

5. The semiconductor chip package of claim 1, wherein the at least one opening comprises a single opening that is disposed at a substantially center portion of the backside surface of the semiconductor chip.

6. The semiconductor chip package of claim 1, wherein the at least one opening are disposed at edge portions of the backside surface of the semiconductor chip and expose a portion of the side surfaces of the semiconductor chip.

7. The semiconductor chip package of claim 6, wherein the at least one opening includes a first opening and a second opening collectively defining the at least one opening.

8. The semiconductor chip package of claim 7, wherein the first opening exposes a portion of the backside surface of the semiconductor chip adjacent to one of the edges of the semiconductor chip and the second opening exposes a portion of the side surface of the semiconductor chip that is adjacent to the one of the edges of the semiconductor chip.

9. The semiconductor chip package of claim 6, wherein the exposed portion of the side surface and the exposed portion of the backside surface forms a step within the at least one opening.

10. The semiconductor chip package of claim 6, wherein the at least one opening is formed at a substantially center portion of the corresponding edge of the semiconductor chip.

11. The semiconductor chip package of claim 10, wherein the at least one opening comprise four openings disposed at substantially center portions of the corresponding edges of the semiconductor chip.

12. The semiconductor chip package of claim 1, wherein the external connection terminals are conductive bumps or solder balls.

13. The semiconductor chip package of claim 1, wherein the molding layer comprises at least one of an epoxy molding compound and a silicone material.

14. The semiconductor chip package of claim 1, wherein the external connection terminals are exposed through the molding layer and wherein the molding layer has a substantially concave surface between adjacent ones of the external connection terminals.

15. A multi-chip package, comprising:
a lower substrate;
a first semiconductor chip package disposed on the lower substrate and electrically connected to the lower substrate;
an upper substrate overlying the lower substrate;
a second semiconductor chip package disposed on the upper substrate and electrically connected to the upper substrate; and
a plurality of connection terminals disposed on the lower substrate,
wherein each of the first and second semiconductor chip packages comprises:
a semiconductor chip; and
a molding layer substantially covering a backside surface, side surfaces, and an active surface of the semiconductor chip, wherein the molding layer defines at least one opening exposing a portion of the backside surface of the semiconductor chip.

16. The multi-chip package of claim 15, wherein the at least one opening comprises a single opening that is disposed at a substantially center portion of the backside surface of the semiconductor chip.

17. The multi-chip package of claim 15, wherein the at least one opening comprises a plurality of openings that are disposed at edge portions of the backside surface of the semiconductor chip and expose a portion of the side surfaces of the semiconductor chip.

18. The multi-chip package of claim 15, further comprising one or more sub-PCBs disposed between the upper and lower substrates, wherein the upper substrate is electrically connected to the lower substrate via intermediate external connection terminals disposed on the sub-PCBs.

19. The multi-chip package of claim 15, further comprising:
upper external connection terminals disposed on the first semiconductor chip package; and
lower chip external connection terminals disposed on the second semiconductor chip package.

20. The multi-chip package of claim 19, wherein the upper chip external connection terminals, the lower chip external connection terminals, and the external connection terminals are conductive bumps or solder balls.

21. A method of manufacturing a semiconductor chip package, comprising:
providing a plurality of semiconductor chips on a main mold, each of the semiconductor chips including a backside surface, side surfaces, and an active surface having a plurality of chip pads with external connection terminals disposed thereon, wherein the main mold comprises a plurality of molding spaces and a plurality of projecting portions;
providing a molding material over the semiconductor chips;
providing a subsidiary mold overlying the molding material;
performing a compression molding process such that the molding material fills the molding spaces and forms a molding layer on the backside surfaces, the side surfaces, and the active surfaces of the semiconductor chips; and
separating the main mold from the subsidiary mold.

22. The method of claim 21, further comprising sawing the semiconductor chips into individual semiconductor chip packages.

23. The method of claim 21, wherein performing the compression molding process comprises performing a compression molding process such that the molding material substantially simultaneously forms a molding layer on the backside surfaces, the side surfaces, and the active surfaces of the semiconductor chips.

24. The method of claim 21, further comprising heating the molding material at a temperature range of about 100° C. to about 200° C. and a spiral flow value of 40-140 inch.

25. The method of claim 21, further comprising providing a release tape between the subsidiary mold and the molding material.

26. The method of claim 25, wherein the release tape comprises polytetrafluoroethylene (PTFE), Ethylene TetraFluoroEthylene copolymer (ETFE).

27. The method of claim 21, wherein the molding material comprises at least one of EMC and a silicone material.

28. The method of claim 21, wherein providing the semiconductor chips on the main mold comprises:
adhering the plurality of semiconductor chips on a carrier tape such that the semiconductor chips are spaced apart by a predetermined distance; and
loading the carrier tape on the main mold.

29. The method of claim 28, wherein adhering the semiconductor chips on the carrier tape comprises:
adhering a wafer on the carrier tape;
dicing the wafer into individual semiconductor chips; and
expanding the carrier tape and thereby separating the semiconductor chips.

30. The method of claim 28, wherein separating the main mold from the subsidiary mold comprises removing the carrier tape from the semiconductor chips.

31. The method of claim 21, wherein the projecting portions of the main mold correspond to center portions of the backside surfaces of the semiconductor chips.

32. The method of claim 21, wherein the projecting portions of the main mold correspond to edge portions of the backside surfaces of the semiconductor chips.

33. The method of claim 32, wherein the projecting portions of the main mold comprise:
a step portion configured to contact a portion of the side surfaces of the semiconductor chips; and
a side portion configured to contact a portion of the backside surfaces of the semiconductor chips.

34. The method of claim 32, wherein the backside surface of the semiconductor chips is placed on a top surface of the projecting portions of the main mold.

35. The method of claim 32, wherein each of the projecting portions of the main mold are configured to support a pair of adjacent semiconductor chips.

36. The method of claim 21, wherein the compression molding process causes the molding layer to be formed on the active surfaces of the semiconductor chips between the external connection terminals.

37. The method of claim 21, further comprising forming a release tape over the molding material, wherein separating the main mold from the subsidiary mold comprises removing the release tape from the semiconductor chips.

38. A memory module, comprising:
a substrate; and
a plurality of semiconductor chip packages, each semiconductor chip package including:
a semiconductor chip comprising:
a backside surface;
side surfaces; and
an active surface having a plurality of chip pads;
a plurality of external connection terminals disposed on the chip pads of the semiconductor chip; and
a molding layer, wherein the molding layer substantially covers the backside surface, the side surfaces, and the active surface of the semiconductor chip and wherein the molding layer defines at least one opening exposing a portion of the backside surface of the semiconductor chip.

39. A memory card, comprising:
a controller;
a memory; and
an interface,
wherein the memory comprises a semiconductor chip package, the semiconductor chip package including a molding layer disposed on a backside surface, side surfaces, and an active surface of a semiconductor chip disposed in the semiconductor chip package, and
wherein the molding layer defines at least one opening exposing a portion of the backside surface of the semiconductor chip.

40. The memory card system of claim 39, wherein the controller comprises one or more of a microprocessor, a digital signal processor, and a microcontroller, and
wherein the memory comprises one or more of DRAM, FLASH, PRAM, SRAM, and MRAM.

41. A multi-chip package including:
a lower substrate;
a first semiconductor chip package disposed on the lower substrate and electrically connected to the lower substrate by a plurality of lower chip external connection terminals;
an upper substrate stacked on the lower substrate;
a second semiconductor chip package disposed on the upper substrate and electrically connected to the upper substrate by a plurality of upper chip external connection terminals; and
a plurality of external connection terminals disposed on the lower substrate,
wherein each of the first and second semiconductor chip packages comprises:
a semiconductor chip; and
a molding layer substantially covering a backside surface, side surfaces, and an active surface of the semiconductor chip, wherein the molding layer defines at least one opening exposing a portion of the backside surface of the semiconductor chip.

42. An electronic system, comprising:
a processor;
a memory;
an I/O chip; and
a bus electrically connecting the processor, the memory, and the I/O chip,
wherein the memory comprises a semiconductor chip package, the semiconductor chip package including a molding layer disposed on a backside surface, side surfaces, and an active surface of a semiconductor chip disposed in the semiconductor chip package, wherein the molding layer defines at least one opening exposing a portion of the backside surface of the semiconductor chip.

43. The electronic system of claim 42, wherein the memory comprises one or more of DRAM, FLASH, PRAM, SRAM, and MRAM.

44. A wafer level package, comprising:
a known-good die (KGD) including:
a backside surface;
side surfaces; and
an active surface having a plurality of chip pads;
a plurality of external connection terminals disposed on the chip pads of the die; and
a molding layer, wherein the molding layer substantially covers the backside surface, the side surfaces, and the active surface of the die and wherein the molding layer has at least one opening exposing a portion of the backside surface of the die.

45. The wafer level package of claim 44, wherein the molding layer forms a concave top surface, and wherein a height of the concave top surface of the molding layer is substantially the same or less than a height of the external connection terminals.

46. The wafer level package of claim 44, wherein the height of the concave top surface is higher than half the height of the external connection terminals.
